(19) United States
(12) Patent Application Publication
(10) Pub. No.: US 2010/0264435 A1
(43) Pub. Date: Oct. 21, 2010

(54) White light-emitting diode package structure for simplifying package process and method for making the same

(76) Inventors: Bily Wang, Hsinchu City (TW); Sung-Yi Hsiao, Gongguan Shiang (TW); Jack Chen, Toufen Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/385,819

(22) Filed: Apr. 21, 2009

(51) Int. Cl. H01L 33/00; H01L 21/28

(52) U.S. Cl. 257/98; 438/27; 257/E33.061; 257/E33.067; 257/E21.158

(57) ABSTRACT

A white light-emitting diode package structure for simplifying package process includes a substrate unit, a light-emitting unit, a phosphor unit and a conductive unit. The light-emitting unit is disposed on the substrate, and the light-emitting unit has a positive conductive layer and a negative conductive layer. The phosphor unit has a phosphor layer formed on the light-emitting unit and at least two openings for respectively exposing one partial surface of the positive electrode layer and one partial surface of the negative electrode layer. The conductive unit has at least two conductive wires respectively passing through the two openings in order to electrically connect the positive electrode layer with the substrate unit and electrically connect the negative electrode layer with the substrate unit.

### BACKGROUND OF THE INVENTION

1. Field of the Invention

The present invention relates to a white light-emitting diode package structure and a method for making the same, and particularly relates to a white light-emitting diode package structure for simplifying package process and a method for making the same.

2. Description of Related Art

Referring to FIGS. 1 and 1A to 1E, the prior art provides a method for making a white light-emitting diode package structure for simplifying package process. The method includes following steps:

The step S100 is: referring to FIGS. 1 and 1A, arranging an LED die 1 on a substrate body 3. The LED die 1 has a positive conductive area P and a negative conductive area N formed on its top surface, and the substrate body 3 has a positive conductive pad 3P and a negative conductive pad 3N disposed on its top surface.

The step S102 is: referring to FIGS. 1 and 1B, electrically connecting the positive conductive area P of the LED die 1 with the positive conductive pad 3P of the substrate body 3 and electrically connecting the negative conductive area N of the LED die 1 with the negative conductive pad 3N of the substrate body 3 by using two wires C1.

The step S104 is: referring to FIGS. 1 and 1C, forming a transparent package body T on the substrate body 3 for covering the LED die 1 and the two wires C1.

The step S106 is: referring to FIGS. 1 and 1D, forming a phosphor layer 2 on the transparent package body T.

The step S108 is: referring to FIGS. 1 and 1E, arranging a focusing lens 4 on the substrate body 3 for covering the phosphor layer 2 and the transparent package body T.

Hence, light beams L1 generated by the LED die 1 pass through the phosphor layer 2 to generate white light beams L2, and the white light beams L2 pass through the focusing lens 4 to generate focusing white light beams L3.

However, the light beams L1 can pass through the phosphor layer 2 after passing through the transparent package body T, so that the light beams L1 are refracted easily when passing though the transparent package body T. Therefore, the light-emitting efficiency is reduced by using the transparent package body T.

### SUMMARY OF THE INVENTION

One particular aspect of the present invention is to provide a white light-emitting diode package structure for simplifying package process and a method for making the same. A phosphor layer is formed on an LED die directly and at least two openings pass through the phosphor layer to expose a positive conductive side and a negative conductive side of the LED die. Hence, light beams generated by the LED die can pass through the phosphor layer directly to generate white light beams without passing through a transparent package body. Therefore, the light-emitting efficiency of the present invention is increased by omitting the transparent package body.

In order to achieve the above-mentioned aspects, the present invention provides a white light-emitting diode package structure for simplifying package process, including: a substrate unit, a light-emitting unit, a phosphor unit and a conductive unit. The light-emitting unit is disposed on the substrate. The light-emitting unit has a light-emitting body, a positive conductive layer and a negative conductive layer formed on the light-emitting body, an insulative layer formed between the positive conductive layer and the negative conductive layer, and a light-emitting area formed in the light-emitting body. The phosphor unit has a phosphor layer formed on the light-emitting unit and at least two openings for respectively exposing one partial surface of the positive electrode layer and one partial surface of the negative electrode layer. The conductive unit has at least two conductive wires respectively passing through the two openings in order to electrically connect the positive electrode layer with the substrate unit and electrically connect the negative electrode layer with the substrate unit.

In order to achieve the above-mentioned aspects, the present invention provides a white light-emitting diode package structure for simplifying package process, including: a substrate unit, a light-emitting unit, a phosphor unit and a conductive unit. The light-emitting unit is disposed on the substrate, and the light-emitting unit has a positive conductive layer and a negative conductive layer. The phosphor unit has a phosphor layer formed on the light-emitting unit and at least two openings for respectively exposing one partial surface of the positive electrode layer and one partial surface of the negative electrode layer. The conductive unit has at least two conductive wires respectively passing through the two openings in order to electrically connect the positive electrode layer with the substrate unit and electrically connect the negative electrode layer with the substrate unit.

In order to achieve the above-mentioned aspects, the present invention provides a method for making a white light-emitting diode package structure for simplifying package process, including: providing a wafer having a plurality of light-emitting units, and each light-emitting unit having a light-emitting body, a positive conductive layer and a negative conductive layer formed on the light-emitting body, an insulative layer formed between the positive conductive layer and the negative conductive layer, and a light-emitting area formed in the light-emitting body; forming a phosphor layer on the light-emitting unit; forming at least two openings on the phosphor layer in order to respectively expose one partial surface of the positive electrode layer and one partial surface of the negative electrode layer; cutting the wafer to form a plurality of single light-emitting units separated from each other; respectively arranging the light-emitting units on a plurality of substrate units; and electrically connecting the positive electrode layer of each light-emitting unit with each substrate unit and electrically connecting the negative electrode layer of each light-emitting unit with each substrate unit by at least two conductive wires respectively passing through the two openings.

Hence, light beams generated by the LED die can pass through the phosphor layer directly to generate white light beams without passing through a transparent package body. Therefore, the light-emitting efficiency of the present invention is increased by omitting the transparent package body.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a flowchart of a method for making a white light-emitting diode package structure of the prior art;

FIGS. 1A to 1E are lateral, schematic views of a white light-emitting diode package structure of the prior art, at different stages of the packaging processes, respectively;

FIG. 2 is a flowchart of a method for making a white light-emitting diode package structure for simplifying package process according to the first embodiment of the present invention;

FIGS. 2A to 2C, 2D1, 2D2, and 2E are lateral, schematic views of a white light-emitting diode package structure for simplifying package process according to the first embodiment of the present invention, at different stages of the packaging processes, respectively; and

FIG. 3 is a lateral, schematic view of a white light-emitting diode package structure for simplifying package process according to the second embodiment of the present invention.

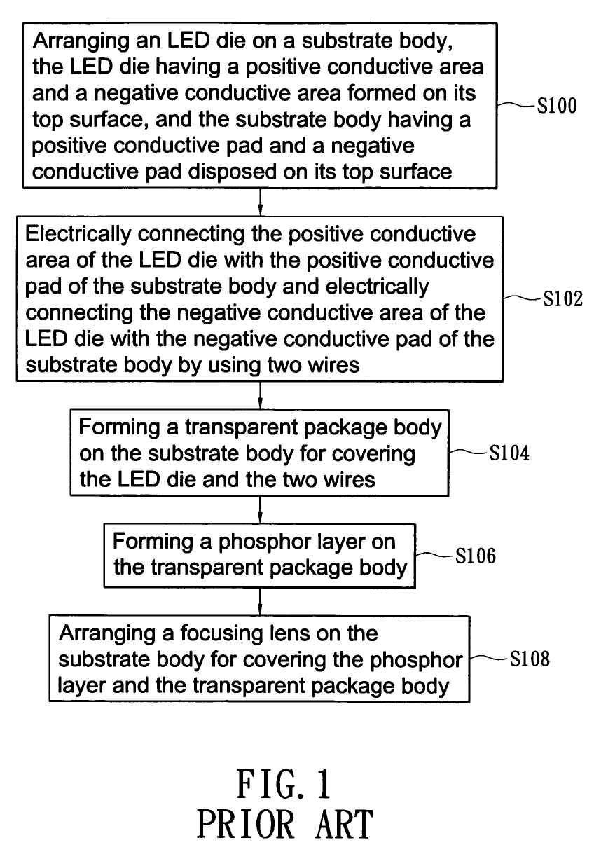

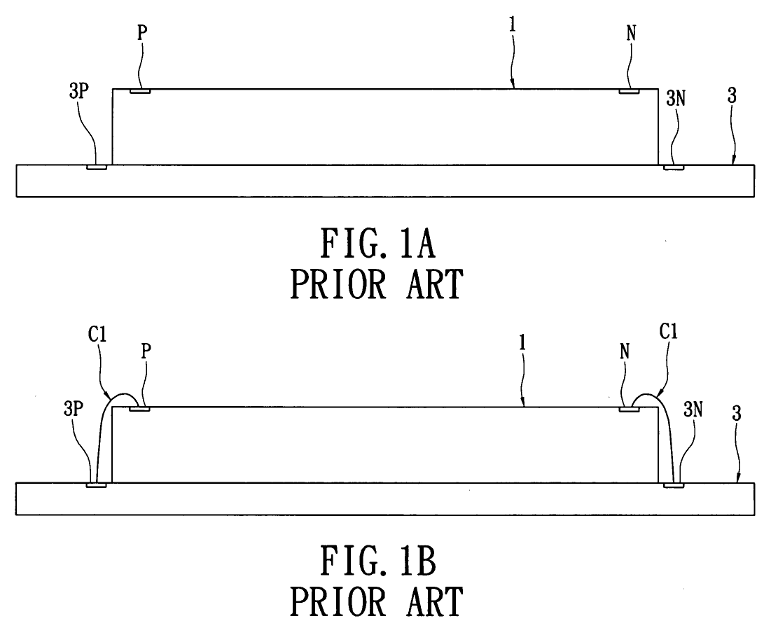

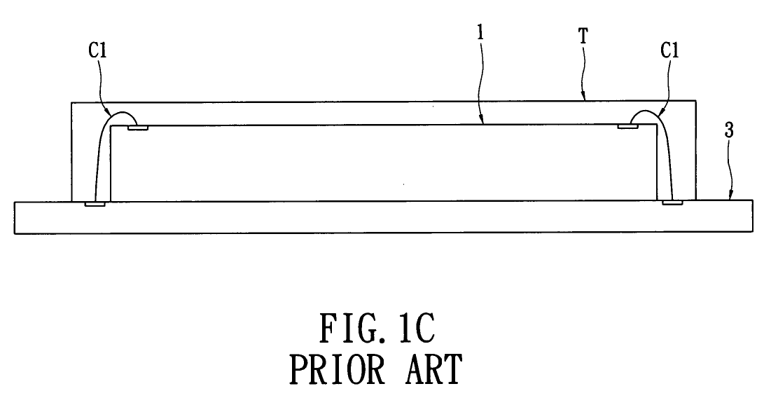

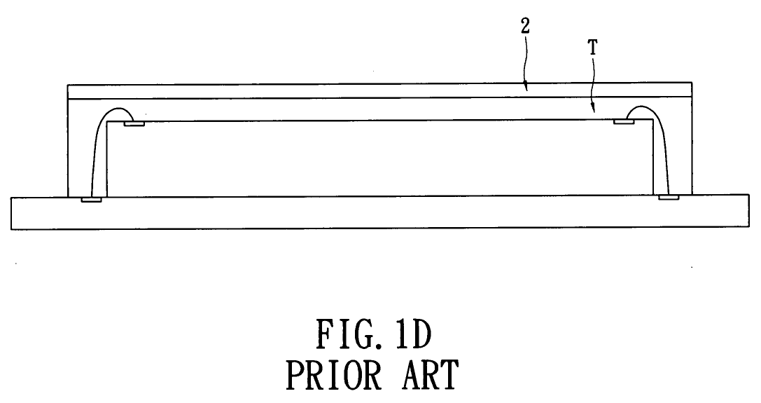

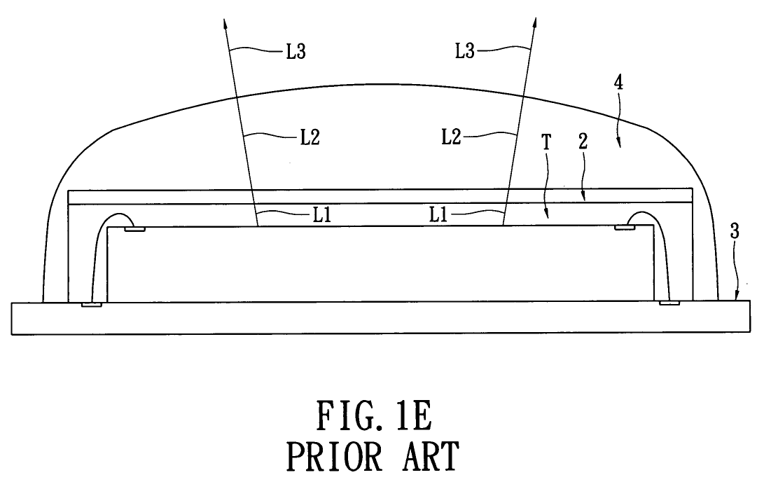

### DETAILED DESCRIPTION OF THE PREFERRED EMBODIMENTS

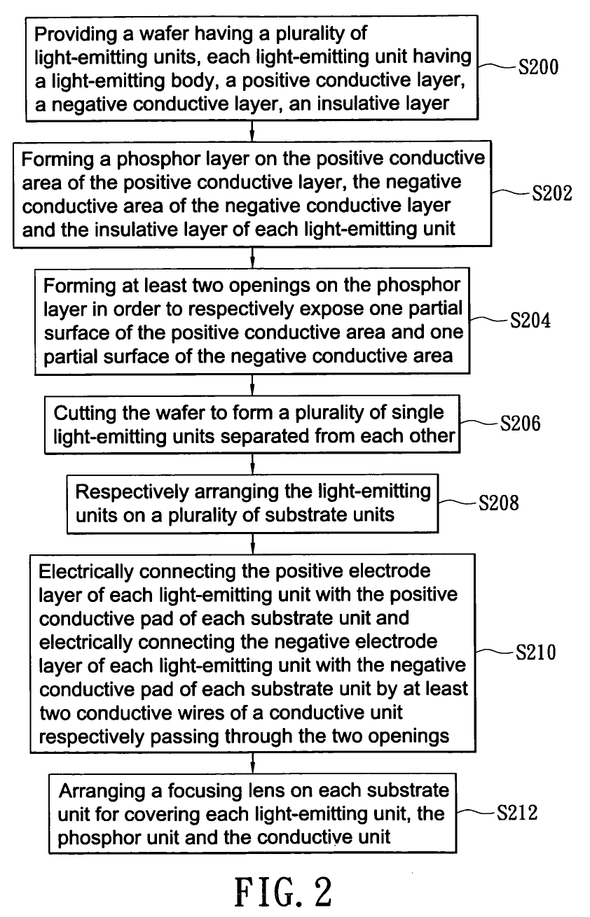

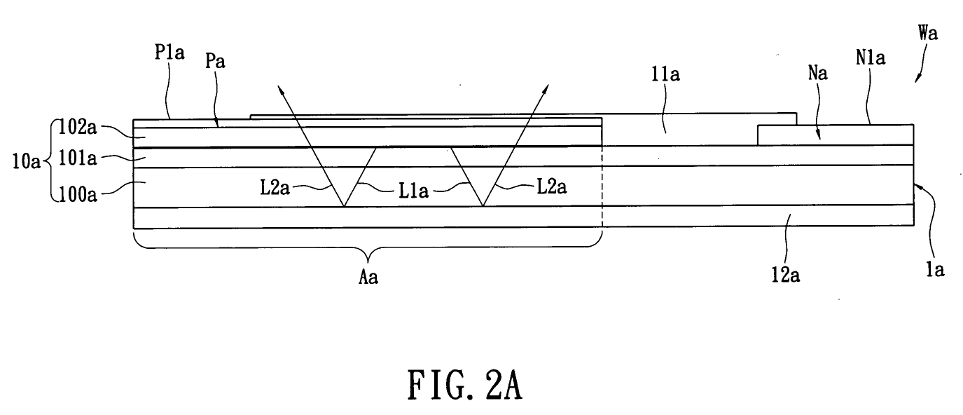

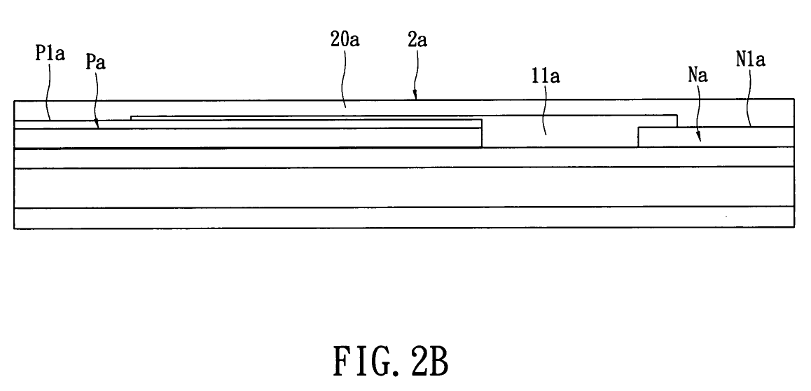

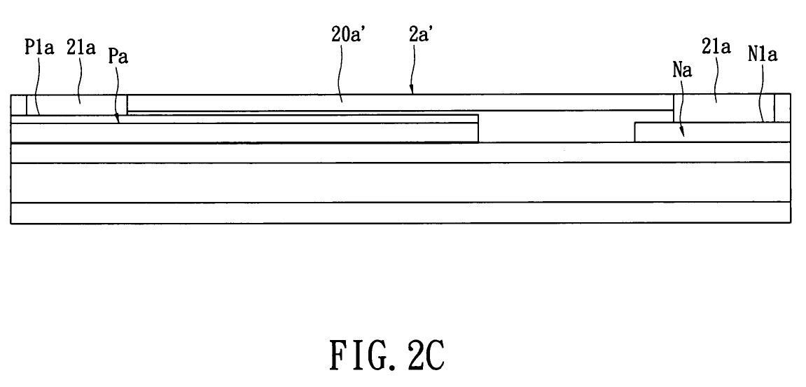

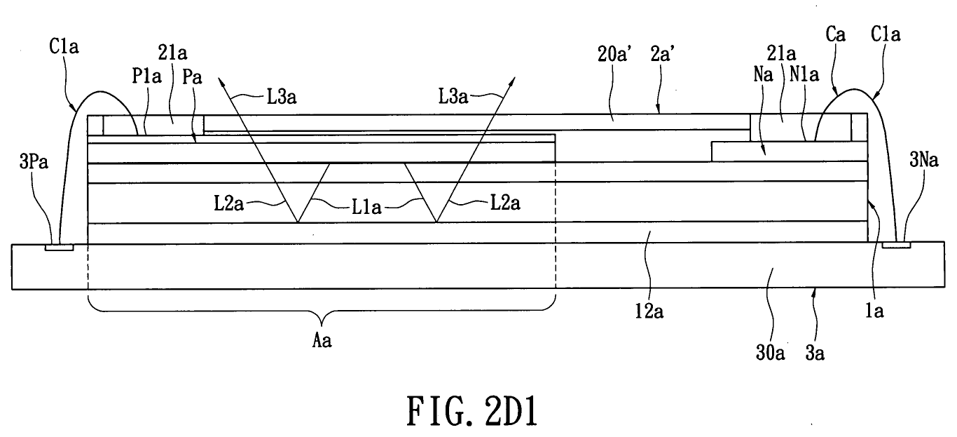

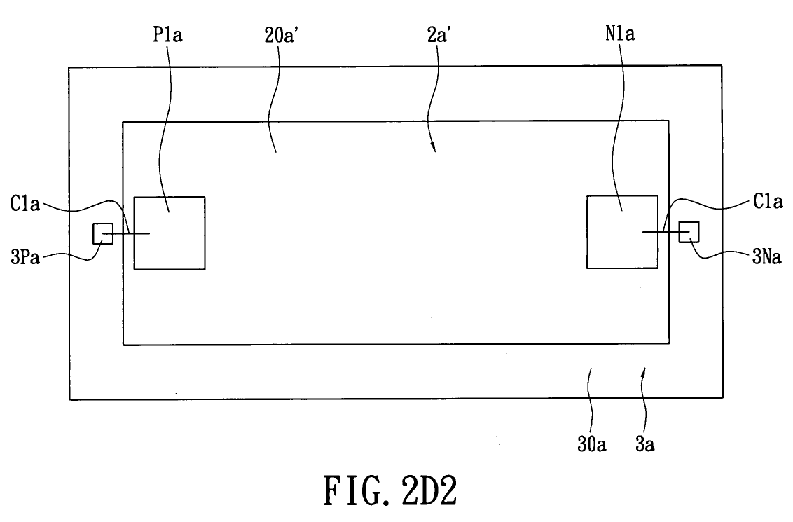

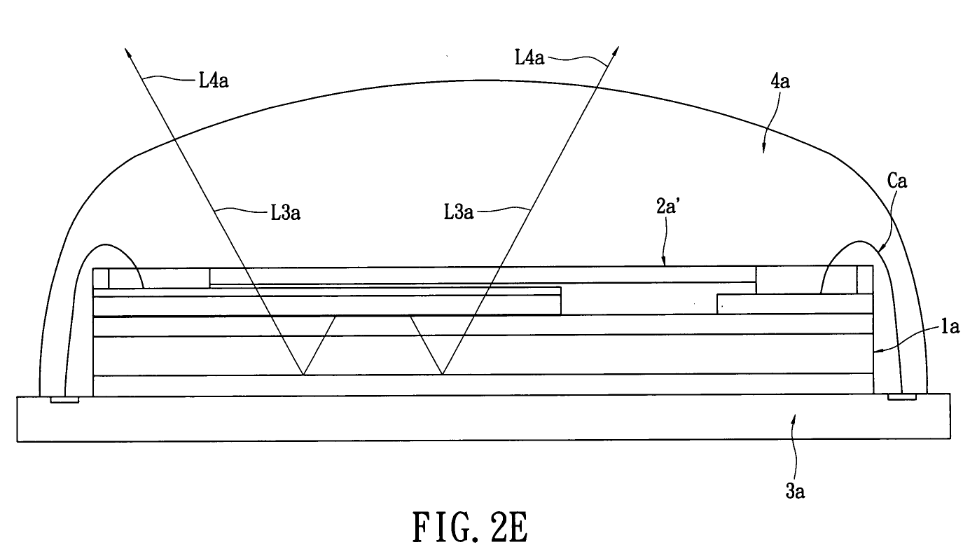

Referring to FIGS. 2 and 2A to 2E, the first embodiment of the present invention provides a method for making a white light-emitting diode package structure for simplifying package process. The method includes following steps:

The step S200 is: referring to FIGS. 2 and 2A, providing a wafer Wa having a plurality of light-emitting units 1a (only shown one light-emitting units 1a in Figures), each light-emitting unit 1a having a light-emitting body 10a, a positive conductive layer Pa (P-type semiconductor material layer) and a negative conductive layer Na (N-type semiconductor material layer) formed on the light-emitting body 10a, an insulative layer 11a formed between the positive conductive layer Pa and the negative conductive layer Na, and a light-emitting area Aa formed in the light-emitting body 10a. In addition, the insulative layers 11a can be polymer layers or ceramic layers.

Moreover, the light-emitting body 10a has an Al₂O₃ substrate 100a, a negative GaN conductive layer 101a formed on the Al₂O₃ substrate 100a, and a positive GaN conductive layer 102a formed on the negative GaN conductive layer 101a. The positive conductive layer Pa is formed on the positive GaN conductive layer 102a, the negative conductive layer Na is formed on the negative GaN conductive layer 101a, and the insulative layer 11a is formed on the negative GaN conductive layer 101a and disposed between the positive conductive layer Pa, the negative conductive layer Na and the positive GaN conductive layer 102a. In addition, the positive conductive layer Pa has a positive conductive area P1a formed on its top surface, the negative conductive layer Na has a negative conductive area N1a formed on its top surface, and one part of the positive conductive area P1a and one part of the negative conductive area N1a are covered by the insulative layer 11a.

Moreover, the light-emitting unit 1a has a reflective layer 12a disposed on a bottom side of the light-emitting body 10a, so that light beams L1a generated from the light-emitting area Aa are reflected by the reflective layer 12a to form upward light beams L2a.

The step S202 is: referring to FIGS. 2 and 2B, forming a phosphor layer 20a (a phosphor unit 2a) on the positive conductive area P1a of the positive conductive layer Pa, the negative conductive area N1a of the negative conductive layer Na and the insulative layer 11a a of each light-emitting unit 1a. In other words, the phosphor layer 20a is formed on the light-emitting unit 1a. In addition, the phosphor layer 20a is mixed by photoresist and phosphor powders, and the photoresist is silicone or epoxy. In other words, the phosphor layer 20a is fluorescent resin that can be formed by mixing silicone and fluorescent powder or mixing epoxy and fluorescent powder.

The step S204 is: referring to FIGS. 2 and 2C, forming at least two openings 21a on the phosphor layer 20a in order to respectively expose one partial surface of the positive conductive area P1a of the positive electrode layer Pa and one partial surface of the negative conductive area N1a of the negative electrode layer Na. The phosphor layer 20a of FIG. 2B becomes a phosphor layer 20a′(a phosphor unit 2a′) as shown in FIG. 2C.

The step S206 is: referring to FIG. 2, cutting the wafer Wa to form a plurality of single light-emitting units 1a separated from each other.

The step S208 is: referring to FIGS. 2, 2D1 and 2D2 (FIG. 2D2 is a top view of FIG. 2D1), respectively arranging the light-emitting units 1a on a plurality of substrate units 3a. Each substrate unit 3a has a substrate body 30a, a positive conductive pad 3Pa disposed on the top surface of the substrate body 30a, and a negative conductive pad 3Na disposed on the top surface of the substrate body 30a.

The step S210 is: referring to FIGS. 2, 2D1 and 2D2, electrically connecting the positive electrode layer Pa of each light-emitting unit 1a with the positive conductive pad 3Pa of each substrate unit 3a and electrically connecting the negative electrode layer Na of each light-emitting unit 1a with the negative conductive pad 3Na of each substrate unit 3a by at least two conductive wires C1a of a conductive unit Ca respectively passing through the two openings 21a. Hence, the light beams L1a generated from the light-emitting area Aa are reflected by the reflective layer 12a to form the upward light beams L2a, the upward light beams L2a pass through the phosphor layer 20a′ in order to generate white light beams L3a.

The step S212 is: referring to FIGS. 2 and 2E, arranging a focusing lens 4a on each substrate unit 3a for covering each light-emitting unit 1a, the phosphor unit 2a′ and the conductive unit Ca. Hence, the white light beams L3a pass through the focusing lens 4a to generate focusing white light beams L4a.

Referring to FIGS. 2D1, 2D2 and 2E, the first embodiment of the present invention provides a white light-emitting diode package structure for simplifying package process, including: a substrate unit 3a, a light-emitting unit 1a, a phosphor unit 2a′ and a conductive unit Ca.

The substrate unit 3a has a substrate body 30a, a positive conductive pad 3Pa disposed on the top surface of the substrate body 30a, and a negative conductive pad 3Na disposed on the top surface of the substrate body 30a.

The light-emitting unit 1a is disposed on the substrate unit 3a. The light-emitting unit 1a has a light-emitting body 10a, a positive conductive layer Pa and a negative conductive layer Na formed on the light-emitting body 10a, an insulative layer 11a formed between the positive conductive layer Pa and the negative conductive layer Na, and a light-emitting area Aa formed in the light-emitting body 10a. In addition, the insulative layers 11a can be polymer layers or ceramic layers.

The light-emitting body 10a has an Al₂O₃ substrate 100a, a negative GaN conductive layer 101a formed on the Al₂O₃ substrate 100a, and a positive GaN conductive layer 102a formed on the negative GaN conductive layer 101a. The positive conductive layer Pa is formed on the positive GaN conductive layer 102a, the negative conductive layer Na is formed on the negative GaN conductive layer 101a, and the insulative layer 11a is formed on the negative GaN conductive layer 101a and disposed between the positive conductive layer Pa, the negative conductive layer Na and the positive GaN conductive layer 102a. In addition, the positive conductive layer Pa has a positive conductive area P1a formed on its top surface, the negative conductive layer Na has a negative conductive area N1a formed on its top surface, and one part of the positive conductive area P1a and one part of the negative conductive area N1a are covered by the insulative layer 11a.

The phosphor unit 2a′ has a phosphor layer 20a′ formed on the light-emitting unit 1a and at least two openings 21a for respectively exposing one partial surface of the positive electrode layer Pa and one partial surface of the negative electrode layer Na.

The conductive unit Ca has at least two conductive wires C1a respectively passing through the two openings 21a in order to electrically connect the positive electrode layer Pa of the light-emitting unit 1a with the positive conductive pad 3Pa of the substrate unit 3a and electrically connect the negative electrode layer Na of the light-emitting unit 1a with the negative conductive pad 3Na of the substrate unit 3a.

Furthermore, the light-emitting unit 1a has a reflective layer 12a disposed on a bottom side of the light-emitting body 10a, so that light beams L1a generated from the light-emitting area Aa are reflected by the reflective layer 12a to form upward light beams L2a, and the upward light beams L2a pass through the phosphor layer 20a′ in order to generate white light beams L3a.

The first embodiment further includes a focusing lens 4a disposed on the substrate unit 3a for covering each light-emitting unit 1a, the phosphor unit 2a′ and the conductive unit Ca. Hence, the white light beams L3a pass through the focusing lens 4a to generate focusing white light beams L4a.

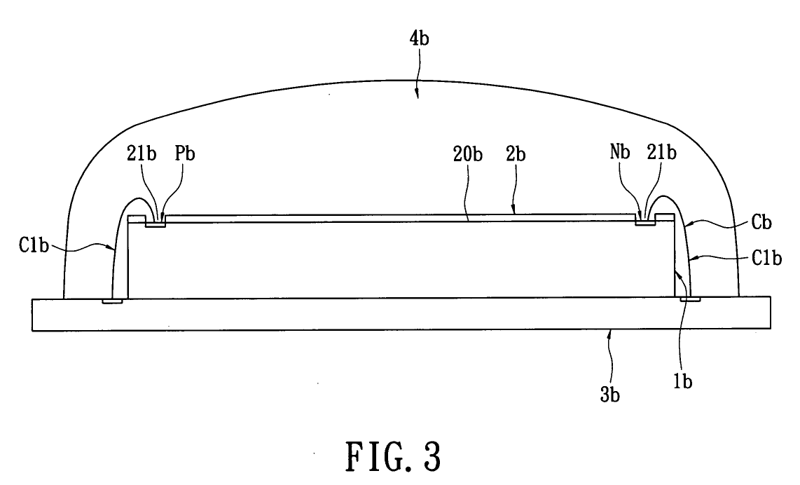

Referring to FIG. 3, the second embodiment of the present invention provides a white light-emitting diode package structure for simplifying package process, including: a substrate unit 3b, a light-emitting unit 1b, a phosphor unit 2b and a conductive unit Cb.

The light-emitting unit 1b is disposed on the substrate unit 3b. The light-emitting unit 1b has a positive conductive layer Pb and a negative conductive layer Nb. The phosphor unit 2b has a phosphor layer 20b formed on the light-emitting unit 1b and at least two openings 21b for respectively exposing one partial surface of the positive electrode layer Pb and one partial surface of the negative electrode layer Nb. The conductive unit Cb has at least two conductive wires C1b respectively passing through the two openings 21b in order to electrically connect the positive electrode layer Pb with the substrate unit 3b and electrically connect the negative electrode layer Nb with the substrate unit 3b. Furthermore, the second embodiment further includes a focusing lens 4b disposed on each substrate unit 3b for covering the light-emitting unit 1b, the phosphor unit 2b and the conductive unit Cb.

In conclusion, the phosphor layer is formed on an LED die (the light-emitting unit) directly and the two openings pass through the phosphor layer to expose a positive conductive side and a negative conductive side of the LED die. Hence, light beams generated by the LED die can pass through the phosphor layer directly to generate white light beams without passing through a transparent package body. Therefore, the light-emitting efficiency of the present invention is increased by omitting the transparent package body.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A white light-emitting diode package structure for simplifying package process, comprising:
a substrate unit;
a light-emitting unit disposed on the substrate, wherein the light-emitting unit has a light-emitting body, a positive conductive layer and a negative conductive layer formed on the light-emitting body, an insulative layer formed between the positive conductive layer and the negative conductive layer, and a light-emitting area formed in the light-emitting body;
a phosphor unit having a phosphor layer formed on the light-emitting unit and at least two openings for respectively exposing one partial surface of the positive electrode layer and one partial surface of the negative electrode layer; and
a conductive unit having at least two conductive wires respectively passing through the two openings in order to electrically connect the positive electrode layer with the substrate unit and electrically connect the negative electrode layer with the substrate unit.

2. The white light-emitting diode package structure as claimed in claim 1, wherein the substrate unit has a substrate body, a positive conductive pad disposed on the top surface of the substrate body, and a negative conductive pad disposed on the top surface of the substrate body.

3. The white light-emitting diode package structure as claimed in claim 2, wherein the two conductive wires are respectively electrically connected between the positive electrode layer and the positive conductive pad and between the negative electrode layer and the negative conductive pad.

4. The white light-emitting diode package structure as claimed in claim 1, wherein the light-emitting body has an Al₂O₃ substrate, a negative GaN conductive layer formed on the Al₂O₃ substrate, and a positive GaN conductive layer formed on the negative GaN conductive layer; the positive conductive layer is formed on the positive GaN conductive layer, the negative conductive layer is formed on the negative GaN conductive layer, and the insulative layer is formed on the negative GaN conductive layer and disposed between the positive conductive layer, the negative conductive layer and the positive GaN conductive layer.

5. The white light-emitting diode package structure as claimed in claim 1, wherein the positive conductive layer has a positive conductive area formed on its top surface, the negative conductive layer has a negative conductive area formed on its top surface, and one part of the positive conductive area and one part of the negative conductive area are covered by the insulative layer.

6. The white light-emitting diode package structure as claimed in claim 1, wherein the insulative layer is a polymer layer or a ceramic layer.

7. The white light-emitting diode package structure as claimed in claim 1, wherein the light-emitting unit has a reflective layer disposed on a bottom side of the light-emitting body, so that light beams generated from the light-emitting area are reflected by the reflective layer to form upward light beams.

8. The white light-emitting diode package structure as claimed in claim 1, wherein the phosphor layer is mixed by photoresist and phosphor powders, and the photoresist is silicone or epoxy.

9. The white light-emitting diode package structure as claimed in claim 1, further comprising: a focusing lens disposed on the substrate unit for covering the light-emitting unit, the phosphor unit and the conductive unit.

10. A white light-emitting diode package structure for simplifying package process, comprising:
a substrate unit;
a light-emitting unit disposed on the substrate, wherein the light-emitting unit has a positive conductive layer and a negative conductive layer;
a phosphor unit having a phosphor layer formed on the light-emitting unit and at least two openings for respectively exposing one partial surface of the positive electrode layer and one partial surface of the negative electrode layer; and
a conductive unit having at least two conductive wires respectively passing through the two openings in order to electrically connect the positive electrode layer with the substrate unit and electrically connect the negative electrode layer with the substrate unit.

11. The white light-emitting diode package structure as claimed in claim 10, further comprising: a focusing lens disposed on the substrate unit for covering the light-emitting unit, the phosphor unit and the conductive unit.

12. A method for making a white light-emitting diode package structure for simplifying package process, comprising:
providing a wafer having a plurality of light-emitting units, wherein each light-emitting unit has a light-emitting body, a positive conductive layer and a negative conductive layer formed on the light-emitting body, an insulative layer formed between the positive conductive layer and the negative conductive layer, and a light-emitting area formed in the light-emitting body;
forming a phosphor layer on the light-emitting unit;
forming at least two openings on the phosphor layer in order to respectively expose one partial surface of the positive electrode layer and one partial surface of the negative electrode layer;
cutting the wafer to form a plurality of single light-emitting units separated from each other;
respectively arranging the light-emitting units on a plurality of substrate units; and
electrically connecting the positive electrode layer of each light-emitting unit with each substrate unit and electrically connecting the negative electrode layer of each light-emitting unit with each substrate unit by at least two conductive wires respectively passing through the two openings.

13. The method as claimed in claim 12, wherein each substrate unit has a substrate body, a positive conductive pad disposed on the top surface of the substrate body, and a negative conductive pad disposed on the top surface of the substrate body.

14. The method as claimed in claim 13, wherein the two conductive wires are respectively electrically connected between the positive electrode layer and the positive conductive pad and between the negative electrode layer and the negative conductive pad.

15. The method as claimed in claim 12, wherein each light-emitting body has an Al₂O₃ substrate, a negative GaN conductive layer formed on the Al₂O₃ substrate, and a positive GaN conductive layer formed on the negative GaN conductive layer; the positive conductive layer is formed on the positive GaN conductive layer, the negative conductive layer is formed on the negative GaN conductive layer, and the insulative layer is formed on the negative GaN conductive layer and disposed between the positive conductive layer, the negative conductive layer and the positive GaN conductive layer.

16. The method as claimed in claim 12, wherein the positive conductive layer has a positive conductive area formed on its top surface, the negative conductive layer has a negative conductive area formed on its top surface, and one part of the positive conductive area and one part of the negative conductive area are covered by the insulative layer.

17. The method as claimed in claim 12, wherein the insulative layer is a polymer layer or a ceramic layer.

18. The method as claimed in claim 12, wherein each light-emitting unit has a reflective layer disposed on a bottom side of the light-emitting body, so that light beams generated from the light-emitting area are reflected by the reflective layer to form upward light beams.

19. The method as claimed in claim 12, wherein the phosphor layer is mixed by photoresist and phosphor powders, and the photoresist is silicone or epoxy.

20. The method as claimed in claim 12, further comprising: arranging a focusing lens on each substrate unit for covering each light-emitting unit, the phosphor unit and the conductive unit.
